(19) United States
(12) Patent Application Publication
(10) Pub. No.: US 2010/0067192 A1
(43) Pub. Date: Mar. 18, 2010

(54) HEAT DISSIPATION DEVICE HAVING FIXTURES FOR ATTACHMENT OF A FAN

(75) Inventors: JIAN LIU, Shenzhen City (CN); JING ZHANG, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (TW); FOXCONN TECHNOLOGY CO., LTD., Tu-Cheng (TW)

(21) Appl. No.: 12/211,044

(22) Filed: Sep. 15, 2008

(51) Int. Cl. H05K 7/20

(52) U.S. Cl. 361/679.47; 361/697; 361/679.45

(57) ABSTRACT

A heat dissipation device includes a heat sink, a fan holder covering the heat sink and formed with a plurality of fastening pins thereon, a fan arranged on the fan holder and mounted on the fastening pins, and a plurality of fixtures mounted on the fastening pins and extending through the fan to secure the fan on the fastening pins of the fan holder. The fan includes a flange having a plurality of fixing holes defined therein for the fastening pins extending therethrough. The fixtures each includes a locking plate locking on a bottom side of the flange of the fan, and a plurality of claws abutting against an upper side of the flange of the fan and clamping on a corresponding fastening pin.

### BACKGROUND OF THE INVENTION

1. Field of the Invention

The present invention relates generally to a heat dissipation device, and more particularly to a heat dissipation device having fixtures for attachment of a fan thereof.

2. Description of Related Art

It is well known that during operation, computer electronic devices such as central processing units (CPU) can generate large amounts of heat. The heat must be quickly removed from the electronic device to prevent it from becoming unstable or being damaged. Typically, a heat sink is attached to an outer surface of the electronic device to absorb heat from the electronic device, and the heat absorbed by the heat sink is then dissipated to ambient air.

Generally, in order to improve heat dissipation efficiency of a heat sink, a fan is used to provide forced airflow to the heat sink. Usually, the fan comprises a frame having upper and lower retaining flanges extending outwards from two opposite ends of each corner thereof, and is mounted to the heat sink via a fan holder. Typically, the fan is secured on the fan holder by a plurality of elongated screws, which each have a head and a shaft extending axially from the head. The fan defines a fixing hole at each retaining flange corresponding to the screw. To attach the fan to the heat sink, the shafts of screws extend through the fixing holes of the fan to engage with the fan holder, whilst the heads of the screws rest on the upper retaining flanges. In this way, the fan is firmly sandwiched between the heads of the screws and the fan holder. However, the assembly of the fan is time-consuming and troublesome.

What is needed, therefore, is a heat dissipation device having fixtures for attachment of a fan, which can overcome the described limitation.

### SUMMARY OF THE INVENTION

A heat dissipation device includes a heat sink, a fan holder covering the heat sink and formed with a plurality of fastening pins thereon, a fan arranged on the fan holder and mounted on the fastening pins, and a plurality of fixtures mounted on the fastening pins and extending through the fan to secure the fan on the fastening pins of the fan holder. The fan includes a flange having a plurality of fixing holes defined therein for the fastening pins to extend therethrough. The fixtures each include a locking plate locking on a bottom side of the flange of the fan, and a plurality of claws abutting against an upper side of the flange of the fan and clamping on a corresponding fastening pin.

Other advantages and novel features will become more apparent from the following detailed description of preferred embodiments when taken in conjunction with the accompanying drawings.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric, exploded view of a heat dissipation device in accordance with a preferred embodiment of the present invention.

FIG. 2 is an enlarged view of a fixture in FIG. 1, with one of claws being cut away to clearly show an inner structure thereof.

FIG. 3 is an isometric, assembled view of the heat dissipation device in FIG. 1.

FIG. 4 is a cross-sectional view taken along line IV-IV of FIG. 3.

### DETAILED DESCRIPTION OF THE INVENTION

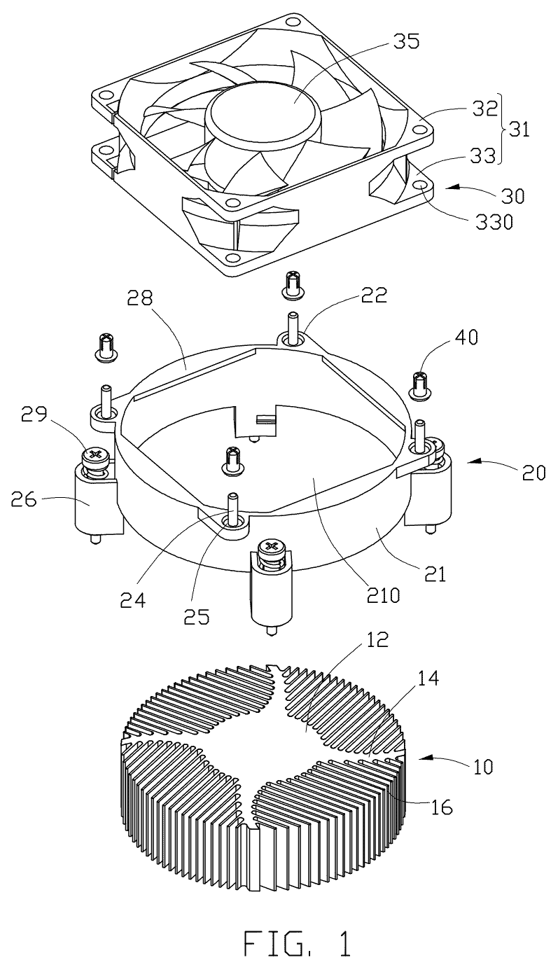

Referring to FIG. 1, a heat dissipation device in accordance with a present embodiment comprises a heat sink 10, a fan holder 20 located on the heat sink 10, a fan 30 arranged on the fan holder 20 and four fixtures 40 mounted on the fan holder 20 to secure the fan 30 on the fan holder 20.

The heat sink 10 has a cylindrical configuration and comprises a cylindrical central core 12 and four curved symmetrical branches 14 radially extending outwardly from a periphery of the core 12. A plurality of fins 16 extends outwardly from the center core 12 and the branches 14.

The fan holder 20 comprises a tubular wall 21 and four spaced top plates 28 extending inwardly and horizontally from a top edge of the tubular wall 21. A central opening 210 is defined by the top plates 28. Airflow generated by the fan 30 can be guided to all parts of the heat sink 10 through the opening 210. Four fastening ears 22 extend outwardly and horizontally from the top edge of the tubular wall 21. Each fastening ear 22 is formed between adjacent two top plates 28. The four fastening ears 22 are symmetrically positioned on a top of a periphery of the tubular wall 21. Top surfaces of the top plates 28 and the fastening ears 22 are coplanar and parallel to a top surface of the heat sink 10. A fastening pin 24 extends upwardly from the top surface of each of the fastening ears 22. An annular groove 25 is defined in each of the fastening ears 22 and surrounds the corresponding fastening pin 24. Four latches 26 are formed near a bottom end of the tubular wall 21. The four latches 26 are symmetrically positioned on the periphery of the tubular wall 21. Every latch 26 is located between two ears 22, and located near a corresponding ear 22. A screw 29 extends through each of the latches 26 to secure the fan holder 20 to a printed circuit board (not shown).

The fan 30 comprises a rectangular bracket 31 and an impeller 35 received in the bracket 31. The bracket 31 includes an upper flange 32 and a bottom flange 33. Four fixing holes 330 are defined in four corners of each of the upper and bottom flanges 32, 33. The fixing holes 330 in the bottom flange 33 are positioned corresponding to the fastening pins 24 of the fan holder 20; thus, the fastening pins 24 can extend through the fixing holes 330 to locate the fan 30 on the fan holder 20.

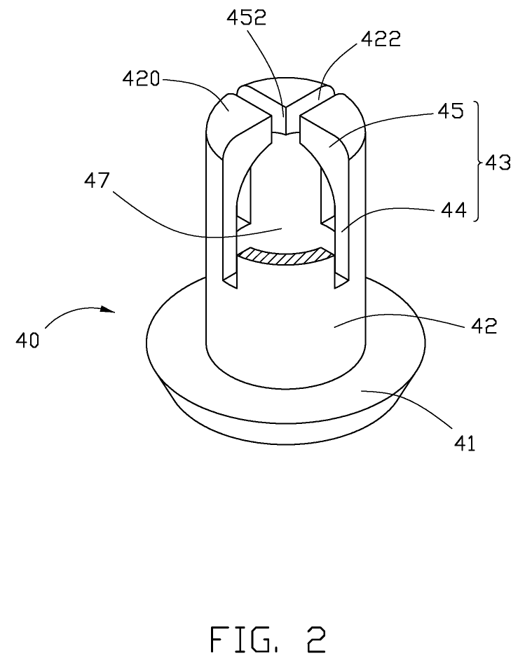

Please also referring to FIG. 2, each fixture 40 comprises a locking plate 41 and a cylindrical shell 42 extending upwardly from a top center of the locking plate 41. The locking plate 41 has a configuration of an inverted frustum, which means that a circular top surface of the locking plate 41 is larger than a circular bottom surface of the locking plate 41, such that the locking plate 41 is fitly received in the annular groove 25 of the fan holder 20. The cylindrical shell 42 forms a top plate 420 perpendicularly extending from a top edge thereof and defines a hole 47 through the top center of the locking plate 41. Four elongated slots 422 extend upwardly from a lower portion of the shell 42, and are evenly defined in the shell 42 and through the top plate 420, in such a manner that the shell 42 forms four claws 43 by the slots 422. The slots 422 are communicated with the hole 47.

Each claw 43 is substantially L-shaped and comprises a flexible portion 44 acting as a part of the shell 42, and a clamping portion 45 extending horizontally and inwardly from a free end of the flexible portion 44 and acting as a part of the top plate 420. A bottom side of the clamping portion 45 is curved and inclined to an inner side of the flexible portion 44. The four claws 43 are symmetrically positioned and spaced from each other. The clamping portions 45 of the fixture 40 are oriented face to face to thereby define a passage 452 in a center thereof which is communicated with the hole 47 in the shell 42.

Each shell 42 has an outer diameter slightly smaller than that of each fixing hole 330 of the fan 30 such that each fixture 40 can extend through the corresponding fixing hole 330 of the fan 30. A diameter of the hole 47 of each fixture 40 is similar to that of each fastening pin 24 of the fan holder 20 so that the each fastening pin 24 can extend through the corresponding hole 47 of the fixture 40. The flexible portions 44 of the claws 43 of each fixture 40 can deform elastically and outwardly after each shell 42 is mounted onto the corresponding fastening pin 24 of the fan holder 20. Due to the elastic deformation of the flexible portions 44, an elasticity oriented to the center of the clamping portions 45 is generated, whereby the clamping portions 45 of the claws 43 clamp on the fastening pin 24.

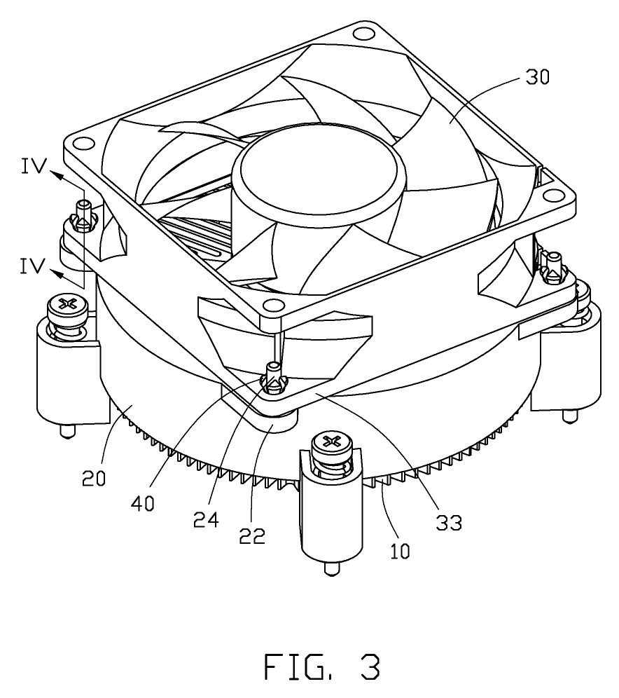

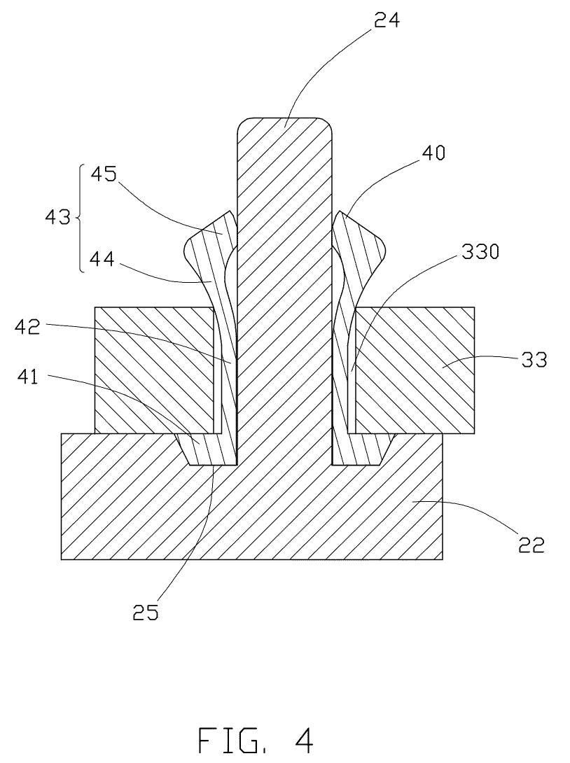

In assembly, referring to FIGS. 3-4, the fan holder 20 covers the heat sink 10. The top plate 28 downwardly abuts against the heat sink 10 and the screws 29 extend through the latches 26 to secure the heat sink 10 and the fan holder 20 on the printed circuit board on which an electric component (not shown) such as a CPU is mounted. Thus, the heat sink 10 can have an intimate contact with the CPU. The fixtures 40 are mounted onto the fastening pins 24, with bottom sides of the clamping portions 45 of the claws 43 attached to top ends of the fastening pins 24. The fan 30 is mounted onto the fastening pins 24 of the fan holder 20, and the fixtures 40 extend through the fixing holes 330 of the bottom flange 33 of the fan 30, with the locking plates 42 of the fixtures 40 attached to a bottom side of the bottom flange 33 of the fan 30.

After that, the fan 30 with the fixtures 40 are pushed down along the fastening pins 24 to attach to the fan holder 20. Outsides of the claws 43 (i.e., the flexible portions 44 of the claws 43) abut against an upper side of the bottom flange 33 of the fan 30, and inner sides of the claws 43 (i.e., the clamping portions 45 of the claws 43) securely clamp on the fastening pins 24 to prevent the fan 30 to slide out of the fastening pins 24. Specifically, the fastening pins 24 extend through the holes 47 in the locking plates 41 and the shells 42 and the passages 452 between the clamping portions 45 of the claws 43. The flexible portions 44 of the claws 43 are elastically expanded outwardly and abutting against the upper side of the bottom flange 33 of the fan 30. The elasticity oriented to the center of the clamping portions 45 and generated due to the elastic deformation of the flexible portions 44 of the claws 43 results in the clamping portions 45 of the claws 43 clamping on the fastening pins 24. The locking plates 41 of the fixtures 40 are received in the grooves 25 of the fan holder 20 and locked on the bottom side of the bottom flange 33.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

1. A heat dissipation device comprising:
a heat sink;
a fan holder covering the heat sink and formed with a plurality of fastening pins thereon;
a fan arranged on the fan holder and mounted on the fastening pins; and
a plurality of fixtures enclosing the fastening pins and extending through the fan to secure the fan on the fan holder, wherein each fixture comprises a plurality of flexible claws with outsides thereof abutting against the fan, and inner sides thereof clamping on a corresponding fastening pin, and is expanded by the corresponding fastening pin to have a secure engagement with the fan and the corresponding fastening pin.

2. (canceled)

3. The heat dissipation device as claimed in claim 1, wherein each of the fixtures further comprises a locking plate sandwiched between the fan holder and the fan, and a shell extending from a top surface of the locking plate and through the fan, a corresponding fastening pin of the fan holder extending upwardly through the locking plate and the shell of the each of the fixtures.

4. The heat dissipation device as claimed in claim 3, wherein the shell comprises a top plate and defines a plurality of slots therein and through the top plate to form the plurality of claws.

5. The heat dissipation device as claimed in claim 4, wherein each of the claws is L-shaped and comprises a flexible portion acting as a part of the shell and a clamping portion extending inwardly from a free end of the flexible portion and acting as a part of the top plate for clamping on the corresponding fastening pin

6. The heat dissipation device as claimed in claim 5, wherein the claws are symmetrically positioned and spaced apart from each other.

7. The heat dissipation device as claimed in claim 5, wherein the fan comprises a frame having a retaining flange, and a plurality of fixing holes is defined in the retaining flange for the fastening pins of the fan holder extending therethrough.

8. The heat dissipation device as claimed in claim 7, wherein the locking plate of the each of the fixture locks on a bottom side of the retaining flange of the fan, and the flexible portions of the claws abut against an upside of the retaining flange and the clamping portions of the claws clamp on the corresponding fastening pin to prevent the retaining flange of the fan from separating from the fastening pins of the fan holder.

9. The heat dissipation device as claimed in claim 3, wherein a plurality of ears extends outwardly from a periphery of the fan holder, and the fastening pins are formed on the ears.

10. The heat dissipation device as claimed in claim 9, wherein a groove is defined in each of the ears and surrounding a corresponding fastening pin for receiving the locking plate of a corresponding fixture therein.

11. A heat dissipation device comprises:
a fan holder with a central hole defined therein, and a plurality of fastening pins formed thereon;
a fan mounted on the fan holder, the fan comprising a flange with a plurality of fixing holes defined therein for the fastening pins extending therethrough; and
a plurality of fixtures mounted on the fastening pins and extending through the fixing holes of the fan, respectively, to secure the fan on the fan holder, each of the fixtures comprising a locking plate locking on a bottom side of the flange of the fan, and a plurality of claws with outsides thereof abutting against an upper side of the flange of the fan and inner sides thereof clamping on a corresponding fastening pin.

12. The heat dissipation device as claimed in claim 11, wherein each of the fixtures further comprises a shell extending upwardly from the locking plate and mounted on a corresponding fastening pin, the claws extending upwardly from an upper end of the shell.

13. The heat dissipation device as claimed in claim 12, wherein each of the claws is L-shaped and comprises a flexible portion acting as a part of the shell and a clamping portion extending inwardly from a free end of the flexible portion, the flexible portions abutting against the upper side of the flange of the fan, the clamping portions clamping on the corresponding fastening pin.

14. The heat dissipation device as claimed in claim 11, wherein a groove is defined around each of the fastening pins for receiving a corresponding locking plate therein.

15. The heat dissipation device as claimed in claim 11, further comprising a heat sink covered by the fan holder, the heat sink having a center core and a plurality of fins radially extending outwardly from the core.

16. The heat dissipation device as claimed in claim 1, wherein each of the fastening pins has a top free end extending upwardly through and beyond a corresponding fixture.

17. The heat dissipation device as claimed in claim 11, wherein each of the fastening pins has a top free end extending upwardly through and beyond a corresponding fixture.
